(19) United States
(12) Patent Application Publication
(10) Pub. No.: US 2024/0260483 A1
(43) Pub. Date: Aug. 1, 2024

(54) METHOD AND DEVICE WITH JOSEPHSON JUNCTION

(71) Applicant: Samsung Electronics Co., Ltd., Suwon-si (KR)

(72) Inventors: Daeseok HAN, Suwon-si (KR); Jaehyeong LEE, Suwon-si (KR); Jinhyoun KANG, Suwon-si (KR); Daeyun KIM, Suwon-si (KR); Jaeho SHIN, Suwon-si (KR); Daeho YANG, Suwon-si (KR)

(73) Assignee: Samsung Electronics Co., Ltd., Suwon-si (KR)

(21) Appl. No.: 18/507,672

(22) Filed: Nov. 13, 2023

(30) Foreign Application Priority Data
Jan. 26, 2023 (KR) 10-2023-0010234

(51) Int. Cl. H10N 60/12; H10N 60/01; H10N 60/80

(52) U.S. Cl. CPC H10N 60/124; H10N 60/0941; H10N 60/805

(57) ABSTRACT

A device including a Josephson junction device including a first superconductor layer, a first oxide layer disposed on a first upper surface of the first superconductor layer, a second superconductor layer disposed to partially overlap the first superconductor layer, a second oxide layer disposed on a second upper surface of the second superconductor layer, and a third superconductor layer including a first portion facing the first upper surface of the first superconductor layer and a second portion facing the second upper surface of the second superconductor layer, and a first thickness of a first portion of the first oxide layer between a lower surface of the first portion of the third superconductor layer and a third upper surface of the first superconductor layer is less than a second thickness of a second portion of the first oxide layer.

### CROSS-REFERENCE TO RELATED APPLICATION

This application is based on and claims priority under 35 U.S.C. § 119 to Korean Patent Application No. 10-2023-0010234, filed on Jan. 26, 2023, in the Korean Intellectual Property Office, the disclosure of which is incorporated by reference herein in its entirety.

### BACKGROUND

### 1. Field

The disclosure provides a method and device with a Josephson junction.

### 2. Description of the Related Art

A qubit is a basic unit of information used in a quantum computer, and is also referred to as a quantum bit. In addition, a qubit may refer to an actual physical device used to store information in a quantum computer or may refer to unit information itself extracted from an actual physical device.

Qubits may be implemented in various ways, such as photon qubits, ion trap qubits, topological qubits, superconducting qubits, etc. Among these, superconducting qubits may typically use a Josephson junction device.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a device including a Josephson junction device including a first superconductor layer, a first oxide layer disposed on a first upper surface of the first superconductor layer, a second superconductor layer disposed to partially overlap the first superconductor layer, a second oxide layer disposed on a second upper surface of the second superconductor layer, and a third superconductor layer including a first portion facing the first upper surface of the first superconductor layer and a second portion facing the second upper surface of the second superconductor layer, and a first thickness of a first portion of the first oxide layer between a lower surface of the first portion of the third superconductor layer and a third upper surface of the first superconductor layer is less than a second thickness of a second portion of the first oxide layer.

The first thickness of the first portion of the first oxide layer may be between approximately 1 nm and 2 nm, and a second thickness of the second portion of the first oxide layer is between approximately 3 nm and 5 nm.

The first oxide layer may extend between a first side surface of the first superconductor layer and a second side surface of the second superconductor layer facing each other so that the first superconductor layer and the second superconductor layer do not directly contact each other.

Each of the first superconductor layer, the second superconductor layer, and the third superconductor layer includes aluminum and each of the first oxide layer and the second oxide layer includes aluminum oxide.

The first superconductor layer may extend to have a first end and a second end, and the second superconductor layer extends to have a first end and a second end, and the first end of the second superconductor layer is disposed to overlap the first end of the first superconductor layer.

The second oxide layer may cover a third side surface of the first end of the second superconductor layer and extends on a fourth upper surface of the first oxide layer to contact the first oxide layer.

A fourth side surface of the first portion of the third superconductor layer may be disposed facing a fifth side surface of the first end of the second superconductor layer, and a lower surface of the second portion of the third superconductor layer may be disposed facing a fifth upper surface of the first end of the second superconductor layer.

The second oxide layer may be disposed between the fourth side surface of the first portion of the third superconductor layer and the fifth side surface of the first end of the second superconductor layer and between the lower surface of the second portion of the third superconductor layer and the fifth upper surface of the first end of the second superconductor layer so that the third superconductor layer and the second superconductor layer do not directly contact each other.

A second thickness of a third portion of the second oxide layer between the fourth side surface of the first portion of the third superconductor layer and the fifth side surface of the first end of the second superconductor layer and between the lower surface of the second portion of the third superconductor layer and the fifth upper surface of the first end of the second superconductor layer may be less than a third thickness of a fourth portion of the second oxide layer.

The second thickness of the third portion of the second oxide layer may be between approximately 1 nm and 2 nm, and the third thickness of the fourth portion of the second oxide layer may be between approximately 3 nm and 5 nm.

The first portion of the third superconductor layer and the first superconductor layer together may include a main Josephson junction, and the first and second portions of the third superconductor layer and the second superconductor layer together form a sub-Josephson junction, a first area of the sub-Josephson junction may be greater than 100 times a second area of the main Josephson junction, and a first value of a critical current of the sub-Josephson junction may be greater than 100 times a second value of a critical current of the main Josephson junction.

A first width of the second portion of the third superconductor layer may be greater than a second width of the first portion of the third superconductor layer.

The Josephson junction device may also include a third oxide layer disposed between a first side surface of the first superconductor layer and a second side surface of the second superconductor layer facing each other.

The first oxide layer may include aluminum oxide, the second oxide layer may include an oxide of a metal material in the second superconductor layer, and the third oxide layer may include an oxide of a metal material in the first superconductor layer.

The device may be a superconducting qubit and further includes a first pad and a second pad that faces the first pad with the Josephson junction device being disposed therebetween. Each of the first superconductor layer, the second superconductor layer, and the third superconductor layer may include superconductor material of TiN, NbN, and/or NbTiN, and each of the second oxide layer and the third oxide layer includes titanium oxide and/or niobium oxide.

In a general aspect, here is provided a superconducting qubit including a first pad, a second pad facing the first pad, and a Josephson junction device provided between the first pad and the second pad, the Josephson junction device may include a first superconductor layer, a first oxide layer disposed on a first upper surface of the first superconductor layer, a second superconductor layer disposed to partially overlap the first superconductor layer, a second oxide layer disposed on a second upper surface of the second superconductor layer, and a third superconductor layer including a first portion facing the first upper surface of the first superconductor layer and a second portion facing the second upper surface of the second superconductor layer, a first thickness of a first portion of the first oxide layer between a lower surface of the first portion of the third superconductor layer and a third upper surface of the first superconductor layer is less than a second thickness of a second portion of the first oxide layer.

The first pad may be electrically connected to the first superconductor layer and the second pad may be electrically connected to the second superconductor layer, and the first superconductor layer and the second superconductor layer extend in a first direction, and the first pad and the second pad extend along a second direction crossing the first direction.

In a general aspect, here is provided a method including forming a first superconductor layer, forming a first oxide layer on a first upper surface of the first superconductor layer by a natural oxidation process, forming a second superconductor layer to partially overlap the first superconductor layer, forming a second oxide layer on a second upper surface of the second superconductor layer by the natural oxidation process, partially removing the first oxide layer and the second oxide layer to reduce a first thickness of a first portion of the first oxide layer and a second thickness of a second portion of the second oxide layer, and forming a third superconductor layer on a partially etched portion of the first oxide layer and a partially etched portion of the second oxide layer.

Each of the first superconducting layer, the second superconducting layer, and the third superconducting layer includes aluminum, and the forming of the first oxide layer may include exposing the first superconductor layer to an atmosphere to naturally oxidize outer surfaces of the first superconductor layer.

Each of the first superconductor layer, the second superconductor layer, and the third superconductor layer may include superconductor material including TiN, NbN, and/or NbTiN, and the forming of the first oxide layer may include forming an aluminum layer on the first upper surface of the first superconductor layer and exposing the aluminum layer to an atmosphere to naturally oxidize the aluminum layer.

In a general aspect, here is provided a method of manufacturing the Josephson junction device including forming an oxide layer on the first upper surface of the first superconductor layer by a natural oxidation process, forming the second superconductor layer to partially overlap the first portion of the first superconductor layer and the second portion of the first oxide layer, forming another oxide layer on the second upper surface of the second superconductor layer by the natural oxidation process, forming the first oxide layer and the second oxide layer by respectively partially removing the oxide layer and the other oxide layer to the first thickness and the second thickness, and forming the third superconductor layer.

The forming of the oxide layer and the forming of the other oxide layer may include naturally oxidizing respective outer surfaces of the first superconductor layer and the second superconductor layer by exposing the respective outer surfaces to an atmosphere.

### BRIEF DESCRIPTION OF THE DRAWINGS

FIG. 1 illustrates an example qubit having a Josephson junction device according to one or more embodiments;

FIG. 2 illustrates an example Josephson junction device according to one or more embodiments;

FIG. 3 illustrates an example third superconductor layer of the Josephson junction device according to one or more embodiments;

FIGS. 4A to 4F illustrates an example process of manufacturing the Josephson junction device according to one or more embodiments;

FIG. 5 is a illustrates an example superconducting qubit according to one or more embodiments;

FIG. 6 illustrates an example electronic circuit according to one or more embodiments;

FIG. 7 illustrates an example Josephson junction device according to one or more embodiments; and

FIGS. 8A to 8E illustrates example methods of manufacturing the Josephson junction device according to one or more embodiments.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

A Josephson junction device may be a structure having a small insulator film being disposed between two superconductors. The insulator film may typically be an oxide. In a typical process of manufacturing a Josephson junction device, a process of completely excluding the formation of a native oxide layer is used, or a thin oxide is intentionally formed again after completely removing the native oxide layer formed during the process. These methods are not suitable for mass production, and the latter method may result in a low yield due to its complexity.

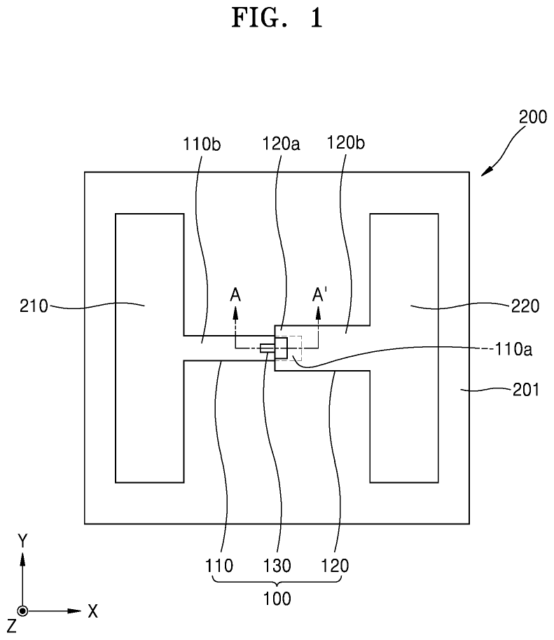

FIG. 1 illustrates a qubit having a Josephson junction device according to one or more embodiments.

Referring to FIG. 1, in a non-limiting example, a superconducting qubit 200 may include a substrate 201, a first pad 210 and a second pad 220 provided to face each other on the substrate 201, and a Josephson junction device 100 provided between the first pad 210 and the second pad 220 on the substrate 201. The substrate 201 may be a silicon substrate or a silicon on insulator (SOI) substrate. However, the substrate 201 is not necessarily limited thereto, and various materials capable of manufacturing the superconducting qubit 200 through a semiconductor process may be used.

The Josephson junction device 100 may include a first superconductor layer 110 extending in a first direction (i.e., X direction), a second superconductor layer 110 extending in the first direction and partially overlapping (e.g., covering)_the first superconductor layer 110, and a third superconductor layer 130 disposed to face a part of an upper surface of the first superconductor layer 110 and a part of an upper surface of the second superconductor layer 120 near an overlapping region of the first superconductor layer 110 and the second superconductor layer 120. The first superconductor layer 110 may extend to include a first end 110a and a second end 110b opposite to the first end 110a. The second superconductor layer 120 may extend to include a first end 120a and a second end 120b opposite to the first end 120a. The first end 120a of the second superconductor layer 120 may be disposed to cover the first end 110a of the first superconductor layer 110.

In an example, the width of the second superconductor layer 120 in a second direction (i.e., Y direction) is wider than the width of the first superconductor layer 110 in the second direction so that the first end 120a of the second superconductor layer 120 covers both the upper surface of the first end 110a of the first superconductor layer 110 and side surfaces thereof in the second direction. However, the arrangement thereof is not necessarily limited thereto. The width of the second superconductor layer 120 in the second direction may be the same as the width of the first superconductor layer 110 in the second direction. In an example, both the first superconductor layer 110 and the second superconductor layer 120 may extend in the first direction but they are not limited thereto. When the first end 120a of the second superconductor layer 120 is disposed to cover the first end 110a of the first superconductor layer 110, the extension direction of the first superconductor layer 110 and the second superconductor layer Extending directions of 120 may be different from each other. In an example, each of the first superconductor layer 110 and the second superconductor layer 120 may be configured in a straight line shape. However, the shapes of the first superconductor layer 110 and the second superconductor layer 120 may have other shape configurations aside from the straight line shape described above.

The first pad 210 may extend in the second direction crossing the first direction, and may be electrically connected to the second end 110b of the first superconductor layer 110. For example, the first pad 210 may include the same material as the first superconductor layer 110 and integrally extend from the second end 110b of the first superconductor layer 110. The second pad 220 may extend in the second direction and may be electrically connected to the second end 120b of the second superconductor layer 120. For example, the second pad 220 may include the same material as the second superconductor layer 120 and may be integrally extended from the second end 120b of the second superconductor layer 120. In an example, the first pad 210 and the first superconductor layer 110 extend in a direction perpendicular to each other, and the second pad 220 and the second superconductor layer 120 may extend in a direction perpendicular to each other. However, their arrangements are not necessarily limited thereto, and the angle between the first pad 210 and the first superconductor layer 110 or the angle between the second pad 220 and the second superconductor layer 120 may be slightly smaller than or greater than 90 degrees.

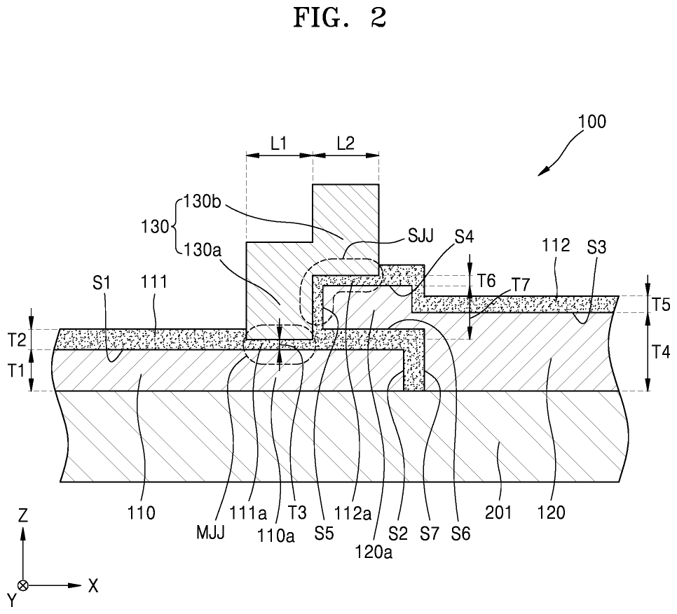

FIG. 2 illustrates an example Josephson junction device in a cross-sectional view taken along line A-A′ of FIG. 1 according to one or more embodiments.

Referring to FIG. 2, in a non-limiting example, the first superconductor layer 110 and the second superconductor layer 120 may be disposed extending in a first direction on an upper surface of the substrate 201. The first end 120a of the second superconductor layer 120 may overlap (e.g., cover)_the first end 110a of the first superconductor layer 110 in a third direction (i.e., Z direction). In other words, the first end 120a of the second superconductor layer 120 may extend on the first end 110a of the first superconductor layer 110 and be disposed to cover the first end 110a of the first superconductor layer 110. A thickness T1 of the first superconductor layer 110 in the third direction is not particularly limited thereto, and may be, for example, about 100 nm or more and about 500 nm or less. A thickness T4 of the second superconductor layer 120 in the third direction is also not particularly limited thereto but may be slightly greater than the thickness T1 of the first superconductor layer 110 so that the first end 120a of the second superconductor layer 120 extends on the first end 110a of the first superconductor layer 110.

In an example, the Josephson junction device 100 may further include a first oxide layer 111 disposed to cover surfaces of the first superconductor layer 110 and a second oxide layer 112 disposed to cover surfaces of the second superconductor layer 120. The first oxide layer 111 may be disposed to cover an upper surface S1 and a side surface S2 of the first superconductor layer 110. The second oxide layer 112 may be disposed to cover upper surfaces S3 and S4 and a side surface S5 of the second superconductor layer 120. Therefore, the first superconductor layer 110 and the second superconductor layer 120 may not directly contact each other. For example, the first oxide layer 111 may be formed between the upper surface S1 of the first superconductor layer 110 and a lower surface S6 of the first end 120a of the second superconductor layer 120 which face each other, and the first oxide layer 111 may be disposed to extend between the side surface S2 of the first superconductor layer 110 and a lower side surface S7 of the second superconductor layer 120 which face each other. The first end 120a of the second superconductor layer 120 may extend in the first oxide layer 111 on the side surface S2 and the upper surface S1 of the first superconductor layer 110 to partially cover the first oxide layer 111. In addition, the second oxide layer 112 may cover the side surface S5 of the first end 120a of the second superconductor layer 120 and extend on the upper surface of the first oxide layer 111 to contact the first oxide layer 111.

In an example, the third superconductor layer 130 may be disposed extending in the third direction so as to face a part of the upper surface S1 of the first superconductor layer 110 and a part of the upper surface S4 of the second superconductor layer 120 near an overlapping region of the first superconductor layer 110 and the second superconductor layer 120. For example, the third superconductor layer 130 may extend from the upper surface S1 of the first superconductor layer 110 to the side surface S5 and upper surface S4 of the first end 120a of the second superconductor layer 120 in a bent form. Therefore, the third superconductor layer 130 may include a first portion 130a facing the upper surface S1 of the first superconductor layer 110 and second portion 130b facing the upper surface S4 of the first end 120a of the second superconductor layer 120. The second portion 130b of the third superconductor layer 130 may overlap (e.g., cover)_the first superconductor layer 110 and the second superconductor layer 120 in a third direction. In addition, the side surface of the first portion 130a of the third superconductor layer 130 may face the side surface S5 of the first end 120a of the second superconductor layer 120.

In a non-limiting example, the third superconductor layer 130 may not directly contact the first superconductor layer 110 and the second superconductor layer 120. For example, the first oxide layer 111 may be present between the lower surface of the first portion 130a of the third superconductor layer 130 and the upper surface S1 of the first superconductor layer 110. In addition, the second oxide layer 112 may be disposed extending between the side surface of the first portion 130a of the third superconductor layer 130 and the side surface S5 of the first end 120a of the second superconductor layer 120 and between the lower surface of the second portion 130b of the third superconductor layer 130 and the upper surface S4 of the first end 120a of the second superconductor layer 120. Therefore, the lower surface of the first portion 130a of the third superconductor layer 130 may directly contact the first oxide layer 111, and the side surface of the first portion 130a of the third superconductor layer 130 and the lower surface of the second portion 130b of the third superconductor layer 130 may directly contact the second oxide layer 112.

In an example, the first portion 130a of the third superconductor layer 130 may form a main Josephson junction MJJ with the first superconductor layer 110. To this end, in an example, a thickness T3 of a portion 111a of the first oxide layer 111 present between the lower surface of the first portion 130a of the third superconductor layer 130 and the upper surface S1 of the first superconductor layer 110 may be small enough that a Josephson junction is formed. Therefore, the thickness T3 of the portion 111a of the first oxide layer 111 present between the first portion 130a of the third superconductor layer 130 and the upper surface S1 of the first superconductor layer 110 may be less than a thickness T2 of another portion of the first oxide layer 111. For example, the thickness T3 of the portion 111a of the first oxide layer 111 present between the first portion 130a of the third superconductor layer 130 and the upper surface S1 of the first superconductor layer 110 may be between approximately 1 nm and 2 nm, and the thickness T2 of the other portion of the first oxide layer 111 may be between approximately 3 nm and 5 nm.

In an example, the side surface of the first portion 130a and the second portion 130b of the third superconductor layer 130 may form a sub Josephson junction SJJ together with the second superconductor layer 120. To this end, a thickness T6 of a portion 112a of the second oxide layer 112 present between the side surface of the first portion 130a of the third superconductor layer 130 and the side surface S5 of the first end 120a of the second superconductor layer 120 and between the lower surface of the second portion 130b of the third superconductor layer 130 and the upper surface S4 of the first end 120a of the second superconductor layer 120 may be small enough that a Josephson junction is formed. In an example, the thickness T6 of the portion 112a of the second oxide layer 112 may be less than a thickness T5 of another portion of the second oxide layer 112. For example, the thickness T6 of the portion 112a of the second oxide layer 112 may be between approximately 1 nm and 2 nm, and the thickness T5 of the other portion of the second oxide layer 112 may be between approximately 3 nm and 5 nm.

Therefore, in a non-limiting example, the Josephson junction device 100 may have two Josephson junctions, that is, the main Josephson junction MJJ may be formed by the first superconductor layer 110 and the third superconductor layer 130 and a second, sub Josephson junction SJJ may be formed by the second superconductor layer 120 and the third superconductor layer 130. In an example, the main Josephson junction MJJ may perform a nonlinear qubit operation and the sub Josephson junction SJJ may have a Josephson effect that is weak enough to be considered as a pure superconductor. In other words, only the main Josephson junction MJJ may substantially contribute to the operation of the Josephson junction device 100 and the sub Josephson junction SJJ may be disregarded. To this end, an area of the sub Josephson junction SJJ may be greater than 100 times or more the area of the main Josephson junction MJJ so that the critical current of the sub Josephson junction SJJ is greater than 100 times or more the critical current of the main Josephson junction MJJ.

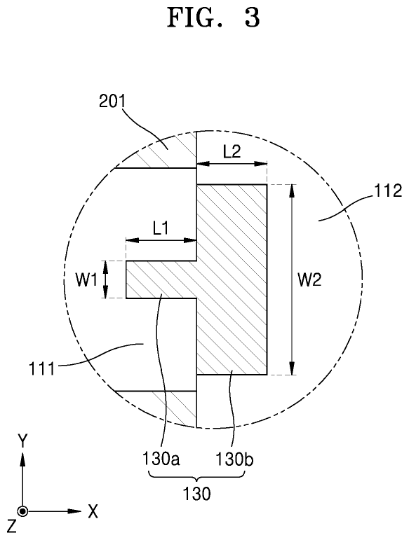

FIG. 3 illustrates an example third superconductor layer of a Josephson junction device, such as the third superconductor layer 130 of the Josephson junction device 100 of FIG. 2 according to one or more embodiments. Referring to FIG. 3, in a non-limiting example, in order to make the area of the sub Josephson junction SJJ greater than the area of the main Josephson junction MJJ, a width W2 of the second portion 130b of the third superconductor layer 130 in the second direction may be greater than a width W1 of the first portion 130a of the third superconductor layer 130 in the second direction.

In an example, the area of the main Josephson junction MJJ is an area where the lower surface of the first portion 130a of the third superconductor layer 130 and the first superconductor layer 110 face each other. Therefore, the area of the main Josephson junction MJJ may be calculated as the product (L1×W1) of the length L1 of the first portion 130a of the third superconductor layer 130 in the first direction and the width W1 of the first portion 130a of the third superconductor layer 130 in the second direction. In addition, the area of the sub Josephson junction SJJ is the sum of the area where the side surface of the first portion 130a of the third superconductor layer 130 and the second superconductor layer 120 face each other and the area where the lower surface of portion 130b of the second superconductor layer 130 and the second superconductor layer 120 face each other. The area where the side surface of the first portion 130a of the third superconductor layer 130 and the second superconductor layer 120 face each other may be calculated as the product (T7×W2) of a thickness (T7, see FIG. 2) in the third direction between the lower surface of the first portion 130a of the third superconductor layer 130 and the upper surface S4 of the first end 120a of the second superconductor layer 120 and the width W2 of the second portion 130b of the third superconductor layer 130 in the second direction. The area where the lower surface of the second portion 130b of the third superconductor layer 130 and the second superconductor layer 120 face each other may be calculated as the product (L2×W2) of a length L2 of the second portion 130b of the third superconductor layer 130 in the first direction and the width W2 of the second portion 130b of the third superconductor layer 130 in the second direction. Therefore, when the area of the main Josephson junction MJJ is ‘A1’ and the area of the sub Josephson junction SJJ is ‘A2’, it may be calculated that A1=L1×W1 and A2=(T7+L2)×W2, and A2 may be greater than 100 times or more A1 (A2≥100A1).

In an example, the width W1 of the first portion 130a of the third superconductor layer 130 in the second direction may be between approximately 500 nm and 10 μm, and the width W2 of the second portion 130b of the third superconductor layer 130 in the second direction may be between approximately 100 μm and 1 mm. In an example, the thickness T7 between the lower surface of the first portion 130a of the third superconductor layer 130 and the upper surface S4 of the first end 120a of the second superconductor layer 120 in the third direction may be between approximately 50 nm and 1 μm, and each of the length L1 of the first portion 130a of the third superconductor layer 130 in the first direction and the length L2 of the second portion 130b of the third superconductor layer 130 in the first direction may be greater than or equal to 100 nm. However, the above numerical values are not limited, and as long as the above-described area condition is satisfied, and the third superconductor layer 130 may have any shape and size.

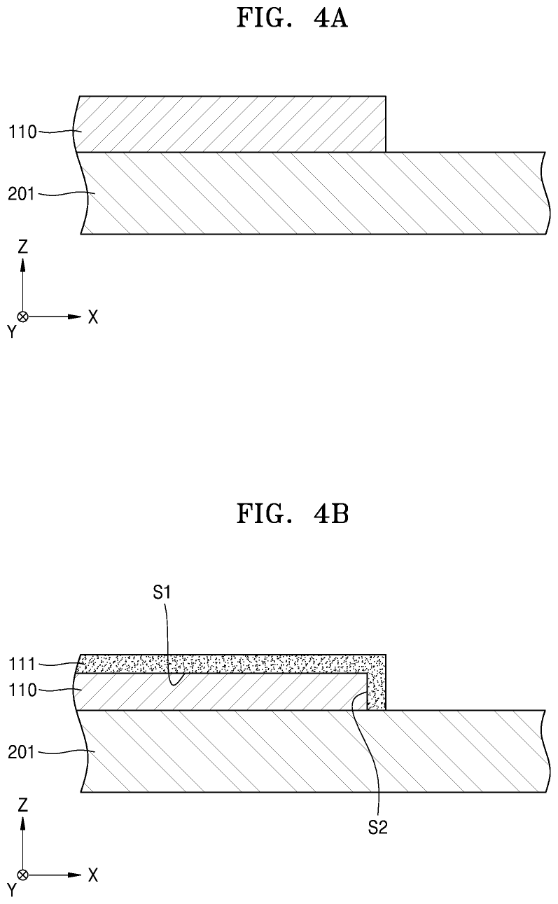

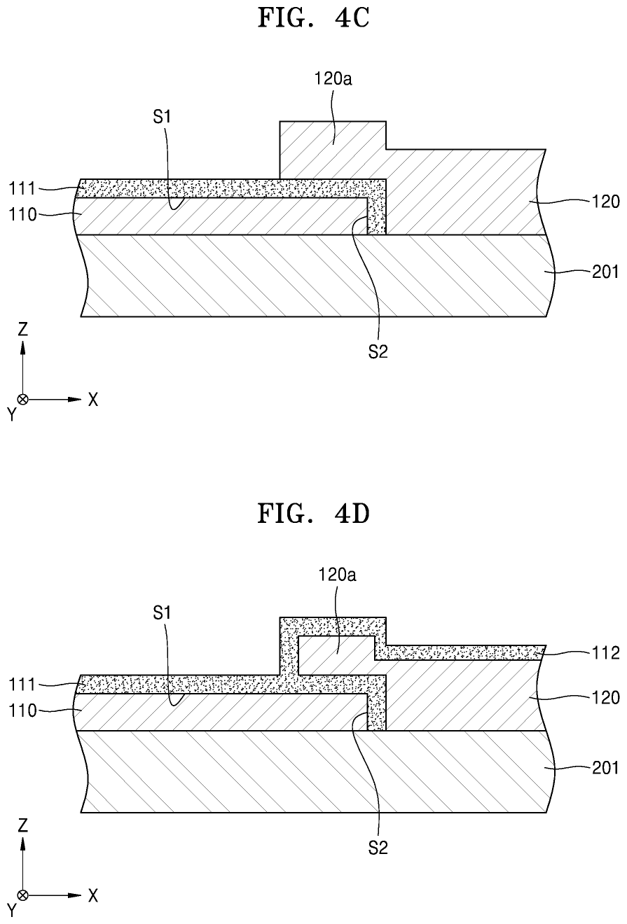

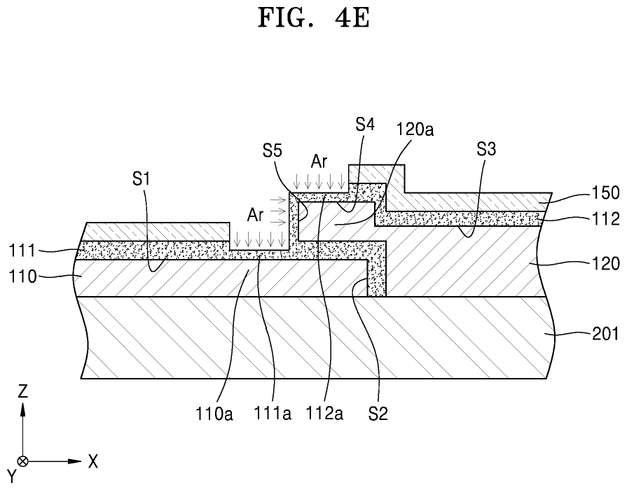

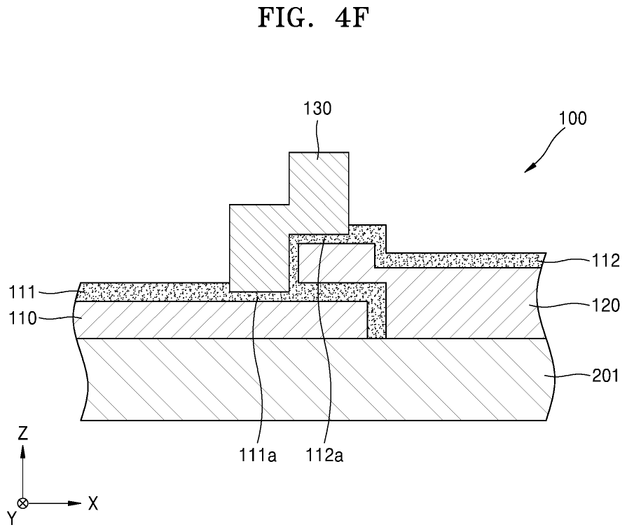

FIGS. 4A to 4F illustrate example methods of manufacturing a Josephson junction device according to one or more embodiments. As a non-limiting example, the manufactured Josephson junction device may by the Josephson junction device 100 of any of FIGS. 1-3.

Referring to FIG. 4A, in a non-limiting example, the first superconductor layer 110 may be formed on the upper surface of the substrate 201. The first superconductor layer 110 may include, for example, aluminum. The first superconductor layer 110 may be integrally formed with the first pad 210 of the superconducting qubit 200 as described above with reference to FIG. 1. For example, aluminum may be deposed on the upper surface of the substrate 201 using physical vapor deposition (PVD), in an example using electron-beam PVD, and then patterned to have the shape of the first pad 210 of the superconducting qubit 200 and the first superconductor layer 110 of the Josephson junction device 100. The first superconductor layer 110 may be deposited to a thickness of, for example, approximately 100 nm or more. Patterning of the first superconductor layer 110 may be performed by, for example, photolithography.

Referring to FIG. 4B, in a non-limiting example, external surfaces of the first superconductor layer 110 may be oxidized in a natural oxidation manner by exposing the first superconductor layer 110 to the atmosphere for a predetermined period of time. Then, the first oxide layer 111 may be formed on surfaces of the first superconductor layer 110. Accordingly, the first oxide layer 111 may include aluminum oxide. FIG. 4B illustrates an example that the first oxide layer 111 may be formed on the upper surface S1 and the side surface S2 of the first superconductor layer 110 for convenience, and the first oxide layer 111 may be formed on all surfaces of the first superconductor layer 110 that are exposed to the atmosphere. The exposure time may be set to a time during which the first oxide layer 111 is formed to a thickness of, for example, between approximately 3 nm and 5 nm.

Referring to FIG. 4C, in a non-limiting example, the second superconductor layer 120 may be formed to partially overlap (e.g., cover)_the first superconductor layer 110. The second superconductor layer 120 may include, for example, aluminum. The second superconductor layer 120 may be integrally formed with the second pad 220 of the superconducting qubit 200 as described above with reference to FIG. 1. For example, aluminum may be disposed to cover both the upper surface of the substrate 201 and the first oxide layer 111 on the first superconductor layer 110 using electron beam physical vapor deposition and then patterned to have the shape of the second pad 220 of the superconducting qubit 200 and the second superconductor layer 120 of the Josephson junction device 100. The second superconductor layer 120 may be formed to a thickness of approximately 100 nm or more. The thickness of the second superconductor layer 120 may be thicker than the thickness of layer 110 so that the first end 120a of the second superconductor layer 120 may continuously extend (e.g., cover)_over the first superconductor layer 110 and the first oxide layer 111. Alternatively, in an example, the thickness of the second superconductor layer 120 may be thicker than the sum of the first superconductor layer 110 and the first oxide layer 111 thereon.

Referring to FIG. 4D, in a non-limiting example, external surfaces of the second superconductor layer 120 may be naturally oxidized by exposing the second superconductor layer 120 to the atmosphere for a predetermined period of time. Then, the second oxide layer 112 may be formed on the surfaces of the second superconductor layer 120. Accordingly, the second oxide layer 112 may include aluminum oxide. As in the case of the first superconductor layer 110, the second oxide layer 112 may be formed on all surfaces of the second superconductor layer 120 exposed to the atmosphere. The exposure time may be set to a time during which the second oxide layer 112 is formed to a thickness of, for example, between approximately 3 nm and 5 nm.

Referring to FIG. 4E, in a non-limiting example, the thickness of each of the portion 111a of the first oxide layer 111 and the portion 112a of the second oxide layer 112 may be reduced by partially removing the first oxide layer 111 and the second oxide layer 112 using a reactive ion etching (RIE) process. For example, the first oxide layer 111 and the second oxide layer 112 may be partially removed by plasma using argon gas. The other regions of the first oxide layer 111 and the second oxide layer 112 excluding regions that may be exposed by the argon plasma may be protected from the argon plasma by a mask 150.

In an example, the portion 111a of the first oxide layer 111 and the portion 112a of the second oxide layer 112 exposed by the argon plasma through patterned openings of the mask 150 are located on the first end 110a of the first superconductor layer 110 and the first end 120a of the second superconductor layer 120 near the boundary between the first superconductor layer 110 and the second superconductor layer 120. In addition, the portion 111a of the first oxide layer 111 and the portion 112a of the second oxide layer 112 may continuously extend from the upper surface S1 of the first superconductor layer 110 along the side surface S5 and the upper surface S4 of the first end 120a of the second superconductor layer 120 in a bent form or shape.

In an example, the thickness of each of the portion 111a of the first oxide layer 111 and the portion 112a of the second oxide layer 112 may be adjusted by controlling the atmospheric pressure inside a chamber, radio frequency (RF) power, plasma exposure time, flow rate of argon gas, etc. For example, the RIE process may be performed until the thickness of each of the portion 111a of the first oxide layer 111 and the portion 112a of the second oxide layer 112 has been reduced to be between approximately 1 nm and 2 nm.

Referring to FIG. 4F, in a non-limiting example, the third superconductor layer 130 may be formed on the partially etched portion 111a of the first oxide layer 111 and portion 112a of the second oxide layer 112. The third superconductor layer 130 may include, for example, aluminum. For example, the third superconductor layer 130 may be formed by depositing aluminum on the entirety of the first oxide layer 111 and the second oxide layer 112 and then patterning the aluminum. The mask 150 may then be removed.

The Josephson junction device 100 may be manufactured in the above-described manner. In addition, as illustrated in FIG. 1, when the first pad 210 is integrally formed with the first superconductor layer 110 and the second pad 220 is integrally formed with the first superconductor layer 120, the superconducting qubit 200 including the Josephson junction device 100 may be manufactured simultaneously with the Josephson junction device 100.

In a non-limiting example, in a process of manufacturing the Josephson junction device 100, the Josephson junction device 100 may be manufactured using a naturally forming oxide layer where the natural oxide layer is not completely removed. In addition, the process may also not prevent the formation of the natural oxide layer. For example, each of the first oxide layer 111 and the second oxide layer 112 is a natural oxide layer, and the thickness of each of the first oxide layer 111 and the second oxide layer 112 may be reduced to a thickness suitable for the intended Josephson junction through the RIE process. Therefore, in an example, the Josephson junction device 100 may be manufactured through a relatively simplified process, and the manufacturing time and manufacturing cost of the Josephson junction device 100 may be reduced. In addition, in an example, process errors may be relatively small and mass production may be possible due to the simplicity of the process.

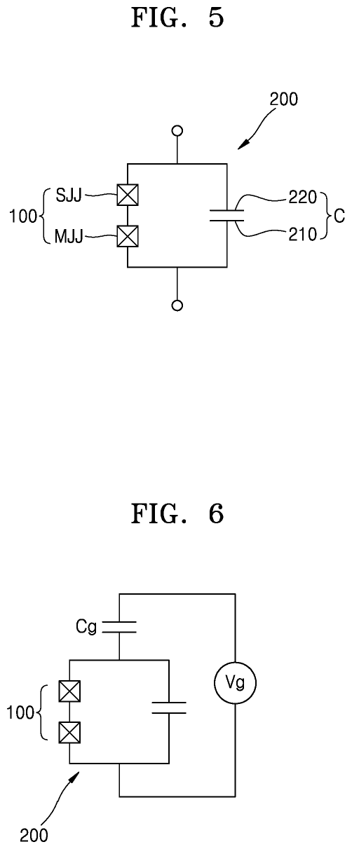

Examples of the Josephson junction device 100 as described above may be used, for example, for a superconducting qubit which is a unit operating device of a quantum computer. FIG. 5 illustrates an example circuit diagram of the superconducting qubit 200 as described above with respect to FIG. 1. Referring to FIG. 5, in a non-limiting example, the superconducting qubit 200 may have a structure in which the Josephson junction device 100 and a capacitor C are connected in parallel. The Josephson junction device 100 may include the main Josephson junction MJJ and the sub Josephson junction SJJ connected in series. Because the critical current of the sub Josephson junction SJJ is much greater than the critical current of the main Josephson junction MJJ, only the main Josephson junction MJJ may substantially contribute to the operation of the Josephson junction device 100 and the sub Josephson junction SJJ may be disregarded. In an example, the capacitor C may include the first pad 210 connected to the main Josephson junction MJJ and the second pad 220 connected to the sub Josephson junction SJJ. The superconducting qubit 200 of the above structure may be referred to as a charge qubit, and in particular, a transmon having a shunted capacitor.

In an example, the Josephson junction device 100 may serve as an inductor, and thus the superconducting qubit 200 may serve as an LC circuit. In an example, because the Josephson junction device 100 is a nonlinear inductor having an inductance that may change according to an applied current, the superconducting qubit 200 may provide an anharmonic oscillator operation. Accordingly, an artificial atom having a plurality of energy levels with different energy gaps may be implemented (e.g., generated).

FIG. 6 illustrates an example electronic circuit that may control a superconducting qubit 200 according to one or more embodiments. In an example, the superconducting qubit may be the superconducting qubit 200 of FIG. 1. Referring to FIG. 6, in a non-limiting example, a gate capacitor Cg may be disposed at one end of the superconducting qubit 200. A state of energy stored in the superconducting qubit 200 may be controlled to be between |0> and |1> through a gate capacitor Cg and a power source Vg connected to the other end of the superconducting qubit 200.

FIGS. 5 and 6 illustrate examples in which the Josephson junction device 100 is applied to a charge qubit, particularly, a transmon, but the Josephson junction device 100 according to the embodiment may be applied to other types of qubits. For example, the Josephson junction device 100 may also be applied to a flux qubit or a phase qubit.

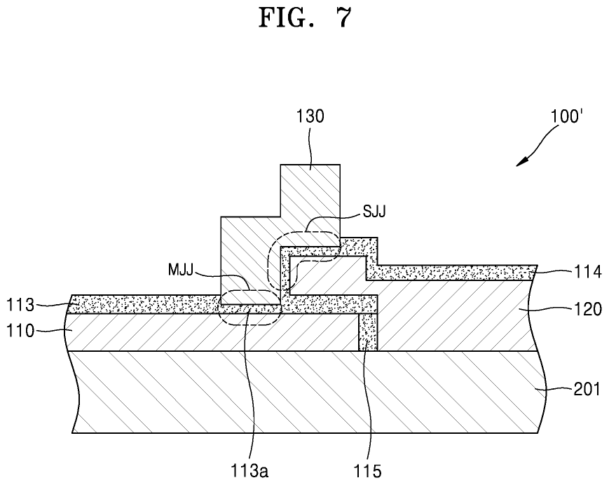

FIG. 7 illustrates an example cross-sectional view of a Josephson junction device according to one or more embodiments. Referring to FIG. 7, in a non-limiting example, the Josephson junction device may be the Josephson junction device 100 as described above in FIG. 2 may use aluminum as a superconductor material and may use a natural oxide layer formed on a surface of the aluminum, but the other materials may be used as the superconductor material. In an example, a Josephson junction device 100′ may include the first superconductor layer 110 on the substrate 201, the first oxide layer 113 disposed on the upper surface of the first superconductor layer 110, the second superconductor layer 120 extending on the first superconductor layer 110 on the substrate 201 and covering a part of the first superconductor layer 110 and a part of the first oxide layer 113, the second oxide layer 114 being disposed to cover surfaces of the second superconductor layer 120, the third superconductor layer 130 being disposed extending in the third direction so as to face a part of the upper surface of the first superconductor layer 110 and a part of the upper surface of the superconductor layer 120 on the boundary between the first superconductor layer 110 and the second superconductor layer 120, and a third oxide layer 115 being disposed between the side surface of the first superconductor layer 110 and the side surface of the second superconductor layer 120 facing each other. Therefore, in an example, the first superconductor layer 110 and the second superconductor layer 120 may not directly contact each other.

In an example, each of the first superconductor layer 110, the second superconductor layer 120, and the third superconductor layer 130 of the Josephson junction device 100′ may include at least one superconductor material of TiN, NbN, or NbTiN. The first oxide layer 113 disposed between the first superconductor layer 110 and the third superconductor layer 130 to form the main Josephson junction MJJ may include aluminum oxide. In an example when aluminum oxide is used as an insulating layer, the main Josephson junction MJJ may have relatively excellent performance. The second oxide layer 114 may be formed by naturally oxidizing a metal material in the first superconductor layer 110. In other words, the second oxide layer 114 may include oxide of a metal material in the first superconductor layer 110. Similarly, the third oxide layer 115 may be formed by naturally oxidizing the metal material in the first superconductor layer 110 and may include an oxide of the metal material in the first superconductor layer 110. For example, the second oxide layer 114 and the third oxide layer 115 may include at least one oxide of titanium oxide or niobium oxide.

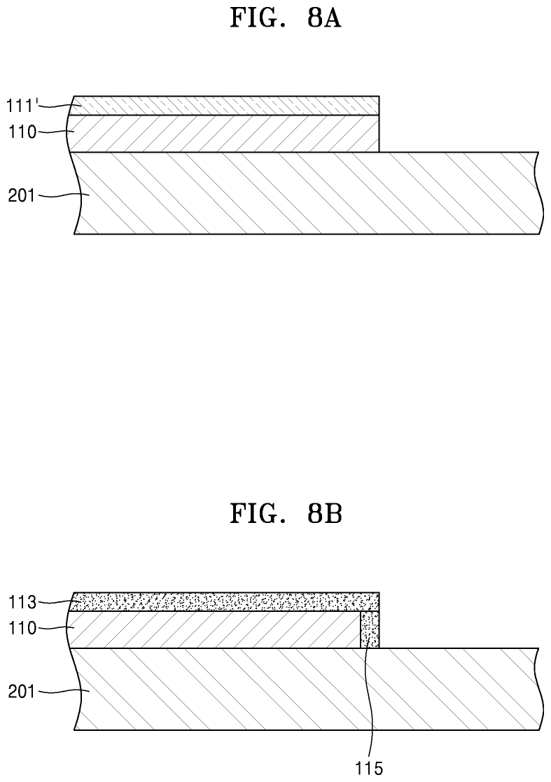

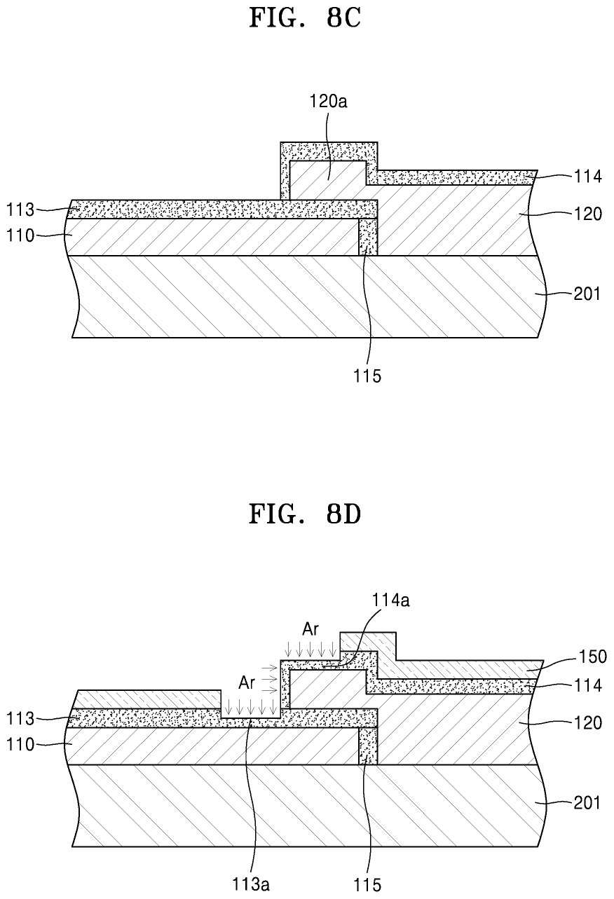

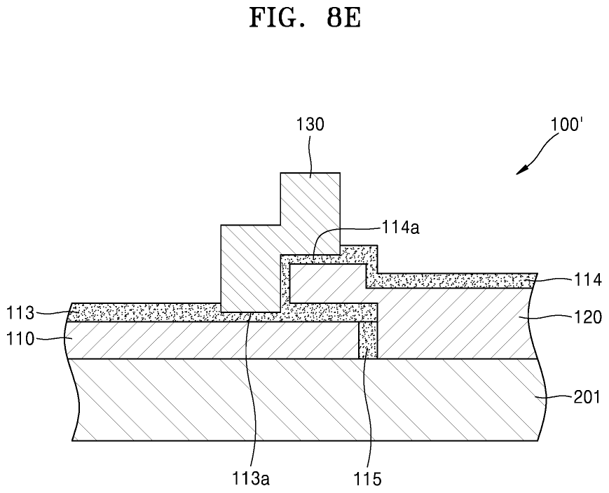

FIGS. 8A to 8E illustrate example cross-sectional views of a process of manufacturing a Josephson junction (e.g., the Josephson junction device 100′ shown in FIG. 7) according to one or more embodiments.

Referring to FIG. 8A, in a non-limiting example, the first superconductor layer 110 may be formed on the upper surface of the substrate 201. The first superconductor layer 110 may include, for example, at least one superconductor material selected from among TiN, NbN, or NbTiN. In addition, an aluminum layer 113′ may be further formed on the upper surface of the first superconductor layer 110. The thickness of the aluminum layer 113′ may be 5 nm or more so that an oxide layer may be sufficiently formed. Then, the first superconductor layer 110 and the aluminum layer 113′ may be patterned to have a shape integral with the first pad 210 of the superconducting qubit 200 shown in FIG. 1.

Referring to FIG. 8B, in a non-limiting example, the aluminum layer 113′ may be exposed to atmosphere for a predetermined period of time to be naturally oxidized by the exposure to the atmosphere. As a result of the oxidation, the first oxide layer 113 may be formed on the upper surface of the first superconductor layer 110. Accordingly, the first oxide layer 113 may include aluminum oxide. Simultaneously, the side surface of the first superconductor layer 110 exposed to the atmosphere may also be oxidized to form the third oxide layer 115. The third oxide layer 115 may include at least one oxide of titanium oxide or niobium oxide.

Referring to FIG. 8C, in a non-limiting example, the second superconductor layer 120 may be formed to partially overlap the first superconductor layer 110. The second superconductor layer 120 may include, for example, a superconductor material such as TiN, NbN, or NbTiN. The thickness of the second superconductor layer 120 may be thicker than the thickness of layer 110 such that the first end 120a of the second superconductor layer 120 may continuously extend on the first superconductor layer 110 and the first oxide layer 113. For example, the thickness of the second superconductor layer 120 may be greater than the sum of the first superconductor layer 110 and the first oxide layer 113 thereon. The second superconductor layer 120 may be patterned to have a shape integral with the second pad 220 of the superconducting qubit 200 shown in FIG. 1. Then, surfaces of the second superconductor layer 120 may be naturally oxidized by exposing the second superconductor layer 120 to the atmosphere for a predetermined period of time. Then, the second oxide layer 114 may be formed on the surface of the second superconductor layer 120.

Referring to FIG. 8D, in a non-limiting example, the thickness of each of the portion 113a of the first oxide layer 113 and of the portion 114a of the second oxide layer 114 may be reduced by partially removing the first oxide layer 113 and the second oxide layer 114 using a RIE process. For example, the first oxide layer 113 and the second oxide layer 114 may be partially removed by plasma using argon gas. The other regions of the first oxide layer 111 and the second oxide layer 112 excluding regions to be exposed by the argon plasma may be protected with the mask 150.

On the other hand, the greater the superconducting energy gap of the superconducting material, the wider the influence range of the proximity effect in a Josephson junction. Therefore, when TiN, NbN, NbTiN, etc. are used as the first superconductor layer 110, the second superconductor layer 120, and the third superconductor layer 130, the thickness of each of the portion 113a of the first oxide layer 113 and of the portion 114a of the second oxide layer 114 may be selected in consideration of the superconducting energy gap of the superconducting material. For example, when TiN, NbN, NbTiN, etc. are used as the first superconductor layer 110, the second superconductor layer 120, and the third superconductor layer 130, the thickness of each of the portion 113a of the first oxide layer 113 and of the portion 114a of the second oxide layer 114 may be 30 nm or less.

Referring to FIG. 8E, in a non-limiting example, the third superconductor layer 130 may be formed on the partially etched portion 113a of the first oxide layer 113 and portion 114a of the second oxide layer 114. The third superconductor layer 130 may include, for example, a superconductor material such as TiN, NbN, or NbTiN. For example, the third superconductor layer 130 may be formed by depositing a superconductor material entirely on the first oxide layer 113 and the second oxide layer 114 and then patterning the superconductor material. Then, the Josephson junction device 100′ may be completed by removing the mask 150.

The Josephson junction device, the superconducting qubit including the Josephson junction device, and the method of manufacturing the Josephson junction device have been described above with reference to the embodiments shown in the drawings, but these are merely exemplary, and it will be understood by those of ordinary skill in the art that various modifications and other equivalent embodiments therefrom are possible. Therefore, the disclosed embodiments should be considered in descriptive sense only and not for purposes of limitation. Therefore, the scope of the disclosure is defined not by the detailed description of the disclosure but by the appended claims, and all differences within the scope will be construed as being included in the disclosure.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A device, comprising:
a Josephson junction device, including:
a first superconductor layer;
a first oxide layer disposed on a first upper surface of the first superconductor layer;
a second superconductor layer disposed to partially overlap the first superconductor layer;
a second oxide layer disposed on a second upper surface of the second superconductor layer; and
a third superconductor layer comprising a first portion facing the first upper surface of the first superconductor layer and a second portion facing the second upper surface of the second superconductor layer,
wherein a first thickness of a first portion of the first oxide layer between a lower surface of the first portion of the third superconductor layer and a third upper surface of the first superconductor layer is less than a second thickness of a second portion of the first oxide layer.

2. The device of claim 1, wherein the first thickness of the first portion of the first oxide layer is between approximately 1 nm and 2 nm, and a second thickness of the second portion of the first oxide layer is between approximately 3 nm and 5 nm.

3. The device of claim 1, wherein the first oxide layer extends between a first side surface of the first superconductor layer and a second side surface of the second superconductor layer facing each other so that the first superconductor layer and the second superconductor layer do not directly contact each other.

4. The device of claim 3, wherein
each of the first superconductor layer, the second superconductor layer, and the third superconductor layer includes aluminum, and
each of the first oxide layer and the second oxide layer includes aluminum oxide.

5. The device of claim 1, wherein the first superconductor layer extends to have a first end and a second end, and the second superconductor layer extends to have a first end and a second end, and
wherein the first end of the second superconductor layer is disposed to overlap the first end of the first superconductor layer.

6. The device of claim 5, wherein the second oxide layer covers a third side surface of the first end of the second superconductor layer and extends on a fourth upper surface of the first oxide layer to contact the first oxide layer.

7. The device of claim 6, wherein a fourth side surface of the first portion of the third superconductor layer is disposed facing a fifth side surface of the first end of the second superconductor layer, and
wherein a lower surface of the second portion of the third superconductor layer is disposed facing a fifth upper surface of the first end of the second superconductor layer.

8. The device of claim 7, wherein the second oxide layer is disposed between the fourth side surface of the first portion of the third superconductor layer and the fifth side surface of the first end of the second superconductor layer and between the lower surface of the second portion of the third superconductor layer and the fifth upper surface of the first end of the second superconductor layer so that the third superconductor layer and the second superconductor layer do not directly contact each other.

9. The device of claim 8, wherein a second thickness of a third portion of the second oxide layer between the fourth side surface of the first portion of the third superconductor layer and the fifth side surface of the first end of the second superconductor layer and between the lower surface of the second portion of the third superconductor layer and the fifth upper surface of the first end of the second superconductor layer is less than a third thickness of a fourth portion of the second oxide layer.

10. The device of claim 9, wherein the second thickness of the third portion of the second oxide layer is between approximately 1 nm and 2 nm, and
wherein the third thickness of the fourth portion of the second oxide layer is between approximately 3 nm and 5 nm.

11. The device of claim 1, wherein the first portion of the third superconductor layer and the first superconductor layer together comprise a main Josephson junction, and the first and second portions of the third superconductor layer and the second superconductor layer together form a sub-Josephson junction,
wherein a first area of the sub-Josephson junction is greater than 100 times a second area of the main Josephson junction, and
wherein a first value of a critical current of the sub-Josephson junction is greater than 100 times a second value of a critical current of the main Josephson junction.

12. The device of claim 11, wherein a first width of the second portion of the third superconductor layer is greater than a second width of the first portion of the third superconductor layer.

13. The device of claim 1, further comprising:
a third oxide layer disposed between a first side surface of the first superconductor layer and a second side surface of the second superconductor layer facing each other.

14. The device of claim 13, wherein the first oxide layer includes aluminum oxide,
wherein the second oxide layer includes an oxide of a metal material in the second superconductor layer, and
wherein the third oxide layer includes an oxide of a metal material in the first superconductor layer.

15. The device of claim 14, wherein the device is a superconducting qubit and further includes a first pad and a second pad that faces the first pad, and with the Josephson junction device being disposed therebetween,
wherein each of the first superconductor layer, the second superconductor layer, and the third superconductor layer includes superconductor material of TiN, NbN, and/or NbTiN, and
wherein each of the second oxide layer and the third oxide layer includes titanium oxide and/or niobium oxide.

16. A superconducting qubit, comprising:
a first pad;
a second pad facing the first pad; and
a Josephson junction device provided between the first pad and the second pad,
wherein the Josephson junction device comprises:
a first superconductor layer;
a first oxide layer disposed on a first upper surface of the first superconductor layer;
a second superconductor layer disposed to partially overlap the first superconductor layer;
a second oxide layer disposed on a second upper surface of the second superconductor layer; and
a third superconductor layer comprising a first portion facing the first upper surface of the first superconductor layer and a second portion facing the second upper surface of the second superconductor layer,
wherein a first thickness of a first portion of the first oxide layer between a lower surface of the first portion of the third superconductor layer and a third upper surface of the first superconductor layer is less than a second thickness of a second portion of the first oxide layer.

17. The superconducting qubit of claim 16, wherein the first pad is electrically connected to the first superconductor layer, and
wherein the second pad is electrically connected to the second superconductor layer, and
wherein the first superconductor layer and the second superconductor layer extend in a first direction, and the first pad and the second pad extend along a second direction crossing the first direction.

18. A method, the method comprising:
forming a first superconductor layer;
forming a first oxide layer on a first upper surface of the first superconductor layer by a natural oxidation process;
forming a second superconductor layer to partially overlap the first superconductor layer;
forming a second oxide layer on a second upper surface of the second superconductor layer by the natural oxidation process;
partially removing the first oxide layer and the second oxide layer to reduce a first thickness of a first portion of the first oxide layer and a second thickness of a second portion of the second oxide layer; and
forming a third superconductor layer on a partially etched portion of the first oxide layer and a partially etched portion of the second oxide layer.

19. The method of claim 18, wherein each of the first superconducting layer, the second superconducting layer, and the third superconducting layer includes aluminum, and
wherein the forming of the first oxide layer comprises exposing the first superconductor layer to an atmosphere to naturally oxidize outer surfaces of the first superconductor layer.

20. The method of claim 18, wherein each of the first superconductor layer, the second superconductor layer, and the third superconductor layer includes superconductor material of TiN, NbN, and/or NbTiN, and
wherein the forming of the first oxide layer comprises:
forming an aluminum layer on the first upper surface of the first superconductor layer; and
exposing the aluminum layer to an atmosphere to naturally oxidize the aluminum layer.
